(19) United States
(12) Patent Application Publication
(10) Pub. No.: US 2008/0224355 A1
(43) Pub. Date: Sep. 18, 2008

(54) METHOD FOR BOW REDUCTION OF A COMPOSITE SHEET

(76) Inventors: Chun-Liang Lin, Tai-Nan City (TW); Yu-Pan Pai, Tai-Nan City (TW)

Correspondence Address: NORTH AMERICA INTELLECTUAL PROPERTY CORPORATION, P.O. BOX 506, MERRIFIELD, VA, 22116, US

(21) Appl. No.: 11/735,442

(22) Filed: Apr. 14, 2007

(30) Foreign Application Priority Data
Mar. 15, 2007 (TW) 096108949

(51) Int. Cl. H01L 31/00

(52) U.S. Cl. 264/348; 136/256

(57) ABSTRACT

A method for bow reduction of a composite sheet includes providing a bow composite sheet including a top sheet and a bottom sheet, the top sheet including a non-metal and the bottom sheet including a metal, and either placing the bow composite sheet on a continuous transportation unit including a cooling unit to substantially eliminate the bow through the cooling unit, or placing the bow composite sheet on a fixed cooling unit spraying a cooling fluid to substantially eliminate the bow.

### BACKGROUND OF THE INVENTION

1. Field of the Invention

The present invention relates to a method for bow reduction. More particularly, the present invention relates to a method for bow reduction of a composite sheet.

2. Description of the Prior Art

A composite sheet generally means a sheet with two different materials attached to each other. For example, a thermocouple is a commonly used composite material sheet.

In the production of solar cells, a thin Al paste is printed on the Si substrate and Al and Si are heated to between 500-700° C. to undergo a chemical reaction. After cooling down, the interface of Al and Si will form a eutectic alloy so that Al is firmly attached to the Si substrate.

Because the eutectic alloy of Al—Si at the interface has a larger thermo expansion coefficient (α=23*10⁻⁶K⁻¹), which is much larger than that of Si (α=3.5*10⁻⁶K⁻¹), the Al—Si composite sheet will bow to form a bowed composite sheet after cooling down. This is not advantageous to following processes of the solar cells.

There are several known fashions to reduce the bow of the solar cells:

1. The Reduction of Al Paste

The easiest way to reduce both the bow of the solar cells and the cost is to reduce the usage of Al paste. But less Al paste will cause the recombination on the surface of the non-alloy range and therefore reduces the efficiency of the solar cells. In addition, the light passes through the substrate directly and the availability of light is lowered, which further lowers the efficiency of the solar cells.

2. Adjustment of the Composition of Al Paste

Some ingredients with very small thermo expansion coefficient can be added into the Al paste to lower the bulk thermo expansion coefficient of the Al paste. However, this could only slightly lower the bow of the solar cells.

3. Reduction of Aggregation Al Paste

This can be done by changing the composition of the Al paste, changing the quantity of the melted glass, or using additives. However, this way will also sacrifice the efficiency of the solar cells.

4. Spray of Liquid Nitrogen

This way can effectively eliminate the bow of the solar cells. But liquid nitrogen has extremely low temperature and is very expensive, the drawbacks are complicated process temperature control, highly dangerous, and increased production cost.

Accordingly, it is necessary to provide a method for efficiently reducing the bow of the solar cells with the advantages of convenient and simple process temperature control, good operational safety, and reasonable production cost.

### SUMMARY OF THE INVENTION

The present invention therefore provides a method for the effective bow reduction of solar cells. The method has the advantages of convenient and simple process temperature control, good operational safety, and reasonable production cost.

The present invention first discloses a method for bow reduction of a composite sheet. Firstly a bowed composite sheet including an upper sheet and a lower sheet is provided. The upper sheet includes a non-metal and the lower sheet includes a metal. Then the composite sheet is placed in a continuous transportation unit including a cooling unit to substantially eliminate the bow of the composite sheet by the cooling unit.

The present invention further discloses a method for bow reduction of a composite sheet. Firstly a bowed composite sheet including an upper sheet and a lower sheet is provided. The upper sheet includes a non-metal and the lower sheet includes a metal. Then the composite sheet is placed in a fixed cooling unit spraying a cooling fluid to substantially eliminate the bow of the composite sheet.

The present invention again discloses a method for bow reduction of a composite sheet. Firstly a bowed composite sheet including an upper sheet and a lower sheet is provided. The upper sheet includes a non-metal and the lower sheet includes a metal. Then the composite sheet is placed in a fixed cooling unit including a cooling plate to substantially eliminate the bow of the composite sheet. The cooling plate contacts the composite sheet.

The method of the present invention uses a cooling unit or sprays a cooling fluid to replace expensive and dangerous liquid nitrogen to eliminate the bow of the composite sheet so that the method has the advantages of convenient and simple process temperature control, good operational safety, and reasonable production cost.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates the first preferred embodiment of the method for bow reduction of a composite sheet of the present invention.

FIG. 2 illustrates that the composite sheet of the present invention is placed in a continuous transportation unit including a cooling unit.

FIG. 3 illustrates the cooling unit of the present invention spraying a cooling fluid on the composite sheet.

FIG. 4 illustrates the cooling plate in the cooling unit of the present invention.

### DETAILED DESCRIPTION

The present invention provides a method for bow reduction of the composite sheets. The method neither traditionally uses expensive and dangerous liquid nitrogen nor intends to adjust the composition of the Al paste to sacrifice the efficiency. The method uses an inexpensive and safe cooling unit or cooling fluid so the method has the advantages of convenient and simple process temperature control, good operational safety, and reasonable production cost.

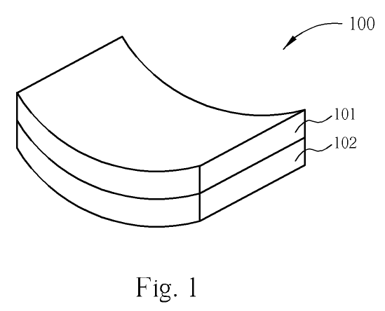

FIG. 1 illustrates the first preferred embodiment of the method for bow reduction of a composite sheet of the present invention. First a bowed composite sheet 100 is provided, which includes an upper sheet 101 and a lower sheet 102. The upper sheet 101 includes a metal such as Al and the lower sheet 102 includes a non-metal such as Si. The composite sheet 100 is preferably a solar cell.

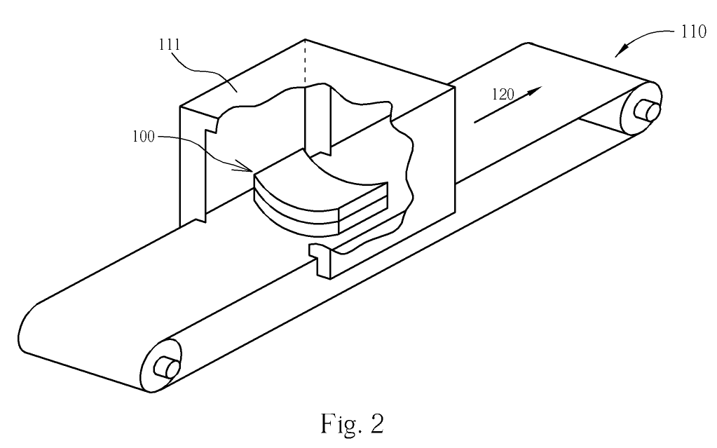

Please refer to FIG. 2. Then the composite sheet 100 is placed facing up or down on a continuous transportation unit 110 including a cooling unit 111 to substantially eliminate the bow of the composite sheet 100 by first cooling down then returning to the room temperature through the cooling unit 111. In order to substantially eliminate the bow of the composite sheet 100, the composite sheet 100 is preferably sufficiently cooled down. For example, for the Al—Si composite sheet, the temperature of the cooling unit may be preferably between −20˜−50° C. to be sufficiently low.

The continuous transportation unit 110 can simultaneously eliminate the bow of the composite sheet 100 and convey the composite sheet 100 to a next stage 120. For example, the continuous transportation unit 110 can be a conveyer or a shuttle between two spots.

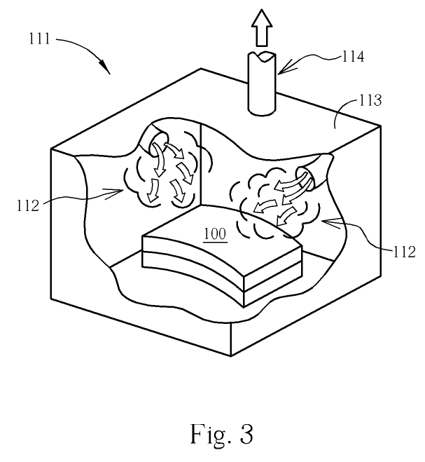

The cooling unit 111 may include many different cooling methods. For example, in FIG. 3, the cooling unit 111 sprays a cooling fluid 112 onto the composite sheet 100 to eliminate the bow of the composite sheet 100. Preferably, the cooling fluid 112 has low toxicity and an operational range between −20˜−50° C. as mentioned before, CO₂, propane or ammonia for example. The phase diagram of CO₂ indicates that it sublimes at −79° C., I atm. CO₂ gas is not toxic and safe and economic to use. To reduce the leakage of the cooling fluid 112, the cooling unit 111 may additionally include a shield 113 such as a curtain or a hood, and a cooling fluid recycling device 114 to keep the cooling fluid from leaking.

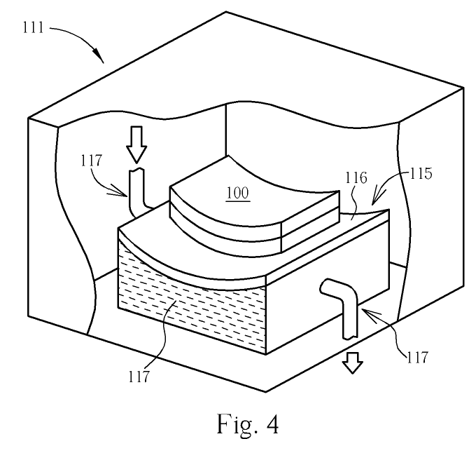

On the other hand, in FIG. 4 the cooling unit 111 may include a cooling plate 114. The bow reduction may also be accomplished by contacting the cooling plate 114 with the lower sheet 102. Preferably, the cooling plate 114 may resemble the bowed shape of the composite sheet 100 to accelerate the cooling-down.

For example, the cooling plate 114 may include a case 116 made of a high heat-conductive material such as a metal and a coolant 117 enclosed in the case 116 or a cooling pipe (not shown) including the coolant 117. The surface temperature of the case 116 can be kept in an ideal low range by the recycling of the coolant 117. Many coolants are suitable, such as CO₂, propane or ammonia . . . etc. The advantage of using the cooling plate 114 is to prevent the leakage of the coolant 117 as much as possible.

In a second preferred embodiment of the method for bow reduction of a composite sheet of the present invention, first a bowed composite sheet is provided, which includes an upper sheet and a lower sheet. The upper sheet includes a non-metal and the lower sheet includes a metal. Preferably, the non-metal may be Si and the metal may be Al. The composite sheet is preferably a solar cell.

Then the composite sheet is placed facing up or down in a fixed cooling unit spraying a cooling fluid, such as a closed metal cooling fixed plate (iron plate or copper plate) spraying propane or ammonia, to substantially eliminate the bow of the composite sheet. The advantages of using the fixed cooling unit are simple design and convenient maintenance. Or in a third preferred embodiment, the composite sheet is placed facing up or down in a fixed cooling unit including a cooling plate to substantially eliminate the bow of the composite sheet. At this time, the cooling plate directly contacts the upper sheet or the lower sheet, such as the one with higher thermo expansion coefficient, of the composite sheet to accelerate the cooling-down.

The temperature of the cooling unit may be between −20˜−50° C. and the cooling unit may additionally include a shield. The shield may keep the cooling fluid from leaking when the cooling fluid is sprayed. The cooling fluid may preferably be CO₂. If the fixed cooling unit including the cooling plate is used, the shield may be used as a thermo-insulation.

The cooling plate may include a case made of a high heat-conductive material such as a metal and a coolant enclosed in the case. The surface temperature of the case may be kept in an ideal low range by the recycling of the coolant. Many coolants are suitable, such as CO₂, propane or ammonia . . . etc. The advantage of using the cooling plate is to prevent the leakage of the coolant as much as possible. Preferably, the cooling plate may resemble the bowed shape of the composite sheet to accelerate the cooling-down.

When the Si substrate with the printed Al paste is taken out from the furnace, it may be kept under the room temperature for a while for cooling down. Then the composite sheet is placed in the cooling unit for a period of time, up to 20 seconds. For example, the composite sheet passes through the cooling unit on a conveyer to be cooled down to an ideal temperature. Finally, the composite sheet is kept for a period of time such as on a conveyer leaving the cooling unit, preferably 20-60 seconds, to return to room temperature to substantially eliminate the bow of the composite sheet, less than 0.2 mm bow for example.

The method of the present invention uses inexpensive and safe cooling unit or cooling fluid to substantially eliminate the bow of the composite sheet so the method has the advantages of convenient and simple process temperature control, good operational safety, and reasonable production cost.

Those skilled in the art will readily observe that numerous modifications and alterations of the device and method may be made while retaining the teachings of the invention.

What is claimed is:

1. A method for a bow reduction of a composite sheet, comprising:
providing a bowed composite sheet comprising an upper sheet and a lower sheet, wherein said upper sheet comprises a non-metal and said lower sheet comprises a metal; and
placing said composite sheet in a continuous transportation unit comprising a cooling unit to substantially eliminate the bow of said composite sheet by said cooling unit.

2. The method of claim 1, wherein said non-metal comprises Si.

3. The method of claim 1, wherein said metal comprises Al.

4. The method of claim 1, wherein said composite sheet is a solar cell.

5. The method of claim 1, wherein said cooling unit is in a temperature between −20˜−50° C.

6. The method of claim 1, wherein said cooling unit eliminates the bow of said composite sheet by spraying a cooling fluid.

7. The method of claim 6, wherein said cooling fluid comprises CO₂.

8. The method of claim 1, wherein said cooling unit comprises a shield to keep said cooling fluid from leaking.

9. The method of claim 1, wherein said cooling unit eliminates the bow of said composite sheet by providing a cooling plate contacting said lower sheet.

10. The method of claim 9, wherein said cooling plate is in a shape resembling the bow of said composite sheet.

11. A method for a bow reduction of a composite sheet, comprising:
providing a bowed composite sheet comprising an upper sheet and a lower sheet, wherein said upper sheet comprises a non-metal and said lower sheet comprises a metal; and
placing said composite sheet in a fixed cooling unit spraying a cooling fluid to substantially eliminate the bow of the composite sheet.

12. The method of claim 11, wherein said non-metal comprises Si.

13. The method of claim 11, wherein said metal comprises Al.

14. The method of claim 11, wherein said composite sheet is a solar cell.

15. The method of claim 11, wherein said cooling unit has a temperature between −20˜−50° C.

16. The method of claim 11, wherein said cooling unit comprises a shield to keep said cooling fluid from leaking.

17. The method of claim 11, wherein said cooling fluid comprises CO₂.

18. A method for a bow reduction of a composite sheet, comprising:
providing a bowed composite sheet comprising an upper sheet and a lower sheet, wherein said upper sheet comprises a non-metal and said lower sheet comprises a metal; and
placing said composite sheet in a fixed cooling unit comprising a cooling plate to substantially eliminate the bow of said composite sheet, wherein said cooling plate contacts the composite sheet.

19. The method of claim 18, wherein said non-metal comprises Si.

20. The method of claim 18, wherein said metal comprises Al.

21. The method of claim 18, wherein said composite sheet is a solar cell.

22. The method of claim 18, wherein said cooling unit has a temperature between −20˜−50° C.

23. The method of claim 18, wherein said cooling unit comprises a shield.

24. The method of claim 18, wherein said cooling plate is in a shape resembling the bow of said composite sheet.

25. The method of claim 18, wherein said cooling plate comprises a coolant.
